(19) United States
(12) Patent Application Publication
(10) Pub. No.: US 2020/0173007 A1
(43) Pub. Date: Jun. 4, 2020

(54) SPUTTERING TARGET PREPARATION PROCESS BASED ON PLASMA SPRAY TECHNOLOGY

(71) Applicant: Helin Ji, Meridian, ID (US)

(72) Inventor: Helin Ji, Meridian, ID (US)

(21) Appl. No.: 16/284,830

(22) Filed: Feb. 25, 2019

(30) Foreign Application Priority Data
Nov. 30, 2018 (CN) 201811447256.1

(51) Int. Cl. C23C 4/134; C23C 14/34; C23C 4/11; C23C 4/18; H01M 4/04

(52) U.S. Cl. CPC C23C 4/134; C23C 14/3414; C23C 14/0652; C23C 4/18; H01M 4/0426; C23C 4/11

(57) ABSTRACT

A process for preparing a sputtering target uses plasma spray technology to prepare a target, having a high density and a high purity comparable to that of an initial powder material. A powder to that is to be sprayed to a particle size range used for plasma spray is processed. a surface of a substrate is subjected to a surface treatment. A plasma sprayer sprays the powder onto the surface of the substrate that underwent surface treatment. The substrate that was sprayed is cleaned. The process can meet the requirements for preparation of large size targets needed to deposit both the electrolyte and the electrode films in the thin-film ion batteries.

### CROSS-REFERENCE TO RELATED APPLICATIONS

This application claims the benefit of priority to Chinese Patent Application No. 201811447256.1 filed on Nov. 30, 2018. The disclosure of the Chinese Application including the specification, drawings, and the claims are hereby incorporated by reference in their entirety.

### TECHNICAL FIELD

The present invention relates to a sputtering target preparation process, in particular to a sputtering target preparation process based on plasma spray technology.

### BACKGROUND

Compared with a conventional lithium ion battery, a thin-film lithium ion battery has certain advantages. The most obvious advantages are small size, high energy density and long cycle life. A thin film lithium ion battery is formed of two electrodes, namely a cathode and an anode, and an electrolyte. For example, a cathode material may be LiCoO₂, LiMn₂O₄, LiFePO₄ or another material. The anode may be C, Si, Ge, Sn or various oxides, nitrides or oxynitrides. Lithium phosphorus oxynitride (LiPON) is one of the most commonly used electrolyte materials in thin film lithium batteries, generally produced by film deposition using a lithium phosphate target in a nitrogen atmosphere by a physical vapour deposition method. The structure of a conventional thin-film battery is described by Bates et al., “Fabrication and characterization of amorphous lithium electrolyte thin films and rechargeable thin-film batteries”, Journal of Power Sources, 43-44 (1993), pp. 103-110, which is hereby incorporated by reference in its entirety.

The prior art demonstrates that the electrolyte is of vital importance to the properties of the battery, hence the manufacture of the sputtering target is also very important. A high-density Li₃PO₄ material suitable for use as a sputtering target is commonly manufactured by two methods, namely sintering and hot press. These two manufacturing methods share the following difficulties:

(1) It is difficult to make the target to a large size. There are two key factors here: one is that Li₃PO₄ is a brittle ceramic material, so mechanical and thermal stress will cause cracking; the second is that as the required furnace chamber size increases, it becomes more and more difficult to control the furnace chamber pressure and temperature uniformity, and in addition the phase diagram is complex, so if it is desired to obtain such a ceramic material of high density and high purity, the temperature window is relatively small.

(2) Gaps. As stated above, it is very difficult for a target of large size to be made in one piece; it is necessary to join multiple pieces, often called tiles, to form one larger piece. However, gaps are possibly one of the reasons for the premature failure of targets. Bonding is required between the target and a backing plate; generally, indium bonding or an electrically conductive bonding that is resistant to high temperatures is used, but this easily leads to contamination.

(3) Phase purity. It is very difficult for high density and pure phase to be present simultaneously. An impurity commonly seen at high temperature and high pressure is Li₄P₂O₇, which is created by the loss of LiO2 from lithium phosphate. Different phases might have different sputtering rates, ultimately causing particles of the target to fall off.

(4) Working gases are generally limited to inert gases and other gases which do not corrode gas chamber components; otherwise they would accelerate consumption or damage of the components in a reaction furnace, in particular, a graphite hot zone. The selection of gases is not as flexible as in a plasma spray method.

Therefore, there is a need for an improved process for preparing a large sputtering target of lithium phosphate material.

### SUMMARY

Technical problem to be solved by the invention: it is difficult for existing processes to meet the requirements for preparation of a large sputtering target of lithium phosphate material. According to an embodiment, a process for preparing a sputtering target that utilizes plasma spray technology includes: processing a powder to be sprayed to a particle size range that is usable for a plasma spray; subjecting a surface of a substrate to surface treatment; spraying the powder using a plasma sprayer onto the treated surface of the substrate to form the sputtering target; cleaning the sputtering target.

According to an embodiment, spraying the powder onto the treated surface of the substrate includes: blowing a working gas into a plasma generation region, under atmospheric-pressure or reduced-pressure conditions; setting an arc direct-current power of the plasma sprayer, and once an are has stabilized, using a carrier gas to feed the powder to be sprayed into a plasma stream; adjusting a spray distance between a head of a spray gun of the plasma sprayer and the treated surface of the substrate, and moving the spray gun of the plasma sprayer to uniformly spray the powder to be sprayed onto a designated region of the substrate.

According to an embodiment, the working gas includes Ar, N₂, O₂, NH₃, air, or another inert gas, and the working gas is blown into the plasma generation region at a flow speed of 1-100 L/min.

According to an embodiment, while the working gas is blown into the plasma generation region, H₂ is added as a secondary working gas.

According to an embodiment, the powder to be sprayed is fed into the plasma stream by the carrier gas at a rate of 1-100 g/min.

According to an embodiment, the arc direct-current power of the plasma sprayer is 1-400 kW.

According to an embodiment, the spray distance is 20-200 mm, and the spray gun of the plasma sprayer moves at a speed of 2-500 cm/s.

According to an embodiment, when the powder to be sprayed is sprayed uniformly onto the designated region of the substrate by the spray gun, a cooling gas stream is blown around a spray flame to control the temperature of the substrate.

According to an embodiment, when the powder to be sprayed is sprayed uniformly onto the designated region of the substrate by the spray gun, cooling water is passed at a back surface of the substrate to control the temperature of the substrate.

According to an embodiment, the temperature of the substrate is controlled so as to be less than or equal to 90% of the melting point of the powder to be sprayed.

According to an embodiment, the particle size range of the powder to be sprayed after processing is 5-500 um.

According to an embodiment, the surface treatment satisfying plasma spray comprises at least one of treatment to enhance adhesion, treatment to adjust a thermal expansion coefficient mismatch, contaminant reduction treatment, surface roughness treatment and treatment to add a surface transition layer; when the surface treatment is performed, one of these treatments or a combination of more than one of these treatments is selected for implementation as required.

According to an embodiment, the substrate is a floating ground, is connected to ground, or has a direct-current offset added.

According to an embodiment, the substrate is a pure metal, alloy, or electrically conductive non-metal material.

According to an embodiment, the powder to be sprayed is a single powder, or a mixed powder of more than one powder, amongst powders used to prepare a solid-state battery electrolyte, or is a single powder, or a mixed powder of more than one powder, amongst powders used to prepare a sodium ion battery positive/negative electrode material.

According to an embodiment, the powders used to prepare a solid-state battery electrolyte include lithium phosphate (Li3PO4), lithium silicate, silicon nitride, lithium iron phosphate, Li(NiCoSi)O2, Li(Mn2O4), silicon, graphite, LiTiO3, LLTO, LLZO and lithium cobaltate; the powders used to prepare a sodium ion battery positive/negative electrode material include sodium-transition metal oxides, sodium-transition metal phosphates and variants, sodium-transition metal sulfates, sodium-transition metal Prussian blue compounds, hard carbon, soft carbon, alloys and transition metal oxides.

Compared with the prior art, the present invention has the following beneficial effects: A major difference between the present invention and hot press and sintering processes is that the target is sprayed directly onto a substrate, with no need for an additional bonding step; the sputtering target prepared by the plasma spray method has a high density (a relative density >93%) and a high purity comparable to that of an initial powder material; compared with a hot press or sintering method, the present invention has definite superiority, and can meet the requirements for preparation of a target needed to produce a thin-film lithium ion battery of large size.

### BRIEF DESCRIPTION OF THE DRAWINGS

FIG. 1 is a flow chart of a preparation process according to an embodiment of the present disclosure.

FIG. 2 is a sectional scanning electron microscope (SEM) image of a sputtering target made by a process according to an embodiment of the present disclosure.

FIG. 3 is a chart indicating X-ray diffraction (XRD) of a sputtering target made by a process according to an embodiment of the disclosure.

### DETAILED DESCRIPTION

While the present disclosure is described herein by way of example using embodiments and illustrative drawings, those skilled in the art will recognize that the disclosure is not limited to the embodiments of drawing or drawings described, and are not intended to represent the scale of the various components. Further, some components that may form a part of the disclosure may not be illustrated in certain figures, for ease of illustration, and such omissions do not limit the embodiments outlined in any way. It should be understood that the drawings and detailed description thereto are not intended to limit the disclosure to the particular form disclosed, but on the contrary, the disclosure is to cover all modifications, equivalents, and alternatives falling within the scope of the present disclosure as defined by the appended claims. As used throughout this description, the word “may” is used in a permissive sense (i.e. meaning having the potential to), rather than the mandatory sense, (i.e. meaning must). Furthermore, the terminology and phraseology used herein is solely used for descriptive purposes and should not be construed as limiting in scope. Language such as “including,” “comprising,” “having,” “containing,” or “involving,” and variations thereof, is intended to be broad and encompass the subject matter listed thereafter, equivalents, and additional subject matter not recited, and is not intended to exclude other additives, components, integers or steps. Likewise, the term “comprising” is considered synonymous with the terms “including” or “containing” for applicable legal purposes. Any discussion of documents, acts, materials, devices, articles and the like is included in the specification solely for the purpose of providing a context for the present disclosure. It is not suggested or represented that any or all of these matters form part of the prior art base or were common general knowledge in the field relevant to the present disclosure.

In this disclosure, whenever a composition or an element or a group of elements is preceded with the transitional phrase “comprising”, it is understood that we also contemplate the same composition, element or group of elements with transitional phrases “consisting of”, “consisting”, “selected from the group of consisting of, “including”, or “is” preceding the recitation of the composition, element or group of elements and vice versa.

The present disclosure is described hereinafter by various embodiments with reference to the accompanying drawing, wherein reference numerals used in the accompanying drawing correspond to the like elements throughout the description. This disclosure may, however, be embodied in many different forms and should not be construed as being limited to the embodiments set forth herein. Rather, the embodiments are provided such that this disclosure will be thorough and complete and will fully convey the scope of the disclosure to those skilled in the art. In the following detailed description, numeric values and ranges are provided for various aspects of the implementations described. These values and ranges are to be treated as examples only, and are not intended to limit the scope of the claims. In addition, a number of materials are identified as suitable for various facets of the implementations. These materials are to be treated as exemplary and are not intended to limit the scope of the disclosure.

The technical solution of the present invention is explained in detail below with reference to the accompanying drawings, but the scope of protection of the present invention is not limited to the embodiments.

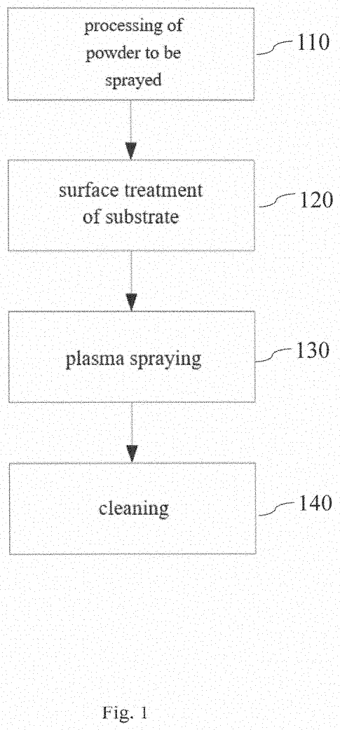

FIG. 1 illustrates a process for preparing a sputtering target utilizing plasma spray technology, according to an embodiment of the present disclosure.

In block 110, a powder that is to be sprayed by a plasma spray is prepared to a particle size range from several micron to hundreds of microns that is suitable for the plasma spray.

In block 120, a surface of a substrate is subjected to a surface treatment that is suitable for the plasma spray.

In block 130, the powder that was prepared in block 110 is sprayed onto the surface of the substrate that underwent surface treatment in block 120. According to an embodiment, plasma sprayer is used to spray the powder onto the treated surface of the substrate.

In block 140, the substrate that was sprayed in step 3 is cleaned and may be tested prior to packaging.

According to an embodiment, block 130 may include: blowing a working gas into a plasma generation region, under atmospheric-pressure or reduced-pressure conditions; setting an are direct-current power of the plasma sprayer, and once an arc has stabilized, using a carrier gas to feed the powder to be sprayed into a plasma stream; and adjusting a spray distance between a head of a spray gun of the plasma sprayer and the treated surface of the substrate, and moving the spray gun of the plasma sprayer with typically a robot to uniformly spray the powder to be sprayed onto a designated region of the substrate.

According to an embodiment, the working gas is Ar, N₂, O₂, NH₃, air or another inert gas, and the working gas is blown into the plasma generation region at a flow speed of 1-100 L/min.

According to an embodiment, while the working gas is blown into the plasma generation region, H₂ may be added as a secondary working gas simultaneously. The function of the secondary working gas H₂ is to control oxygen loss/oxidation, and provide entropy.

According to an embodiment the powder to be sprayed is fed into the plasma stream by the carrier gas at a rate of 1-100 g/min. The carrier gas may be air and/or N₂, and is mainly used for feeding the powder to be sprayed into the plasma stream.

According to an embodiment, the arc direct-current power of the plasma sprayer is 1-400 kW.

According to an embodiment, the spray distance is 20-200 mm, and the spray gun of the plasma sprayer moves with typically a robot at a speed of 2-500 cm/s.

According to an embodiment, when the powder to be sprayed is sprayed uniformly onto the designated region of the substrate by the spray gun, a cooling gas stream is blown around a spray flame to control the temperature of the substrate. The cooling gas may comprise nitrogen or air, and controlling the temperature of the substrate can help to control deformation and increase the powder utilization rate.

According to an embodiment, when the powder to be sprayed is sprayed uniformly onto the designated region of the substrate by the spray gun, cooling water flowing inside the substrate or along the opposite surface of the substrate to control the temperature of the substrate. Controlling the temperature of the substrate can help to reduce deformation and increase the powder utilization rate.

According to an embodiment, the temperature of the substrate is controlled with water, air or interval between sprays so as to be less than or equal to 90% of the melting point of the powder to be sprayed.

According to an embodiment, the powder is prepared to be in the particle size range of 5-500 um.

According to an embodiment, the surface treatment satisfying plasma spray comprises treatment to enhance adhesion, treatment to adjust a thermal expansion coefficient difference value between the backing plate and target material, contaminant reduction treatment, surface roughness treatment, and treatment to add a surface transition layer. For surface roughness treatment, the surface of the substrate may be treated to achieve the right roughness with sandblasting, machining, or similar, and then subsequently cleaned and dried. When the surface treatment is performed, one of these treatments or a combination of more than one of these treatments is selected for implementation as required.

According to an embodiment, the substrate is a floating ground, is connected to ground, or has a direct-current offset added.

According to an embodiment, the substrate is a pure metal, alloy, or electrically conductive non-metal material. Examples are copper, titanium, molybdenum and stainless steel. Furthermore, the powder to be sprayed is a single powder, or a mixed powder of more than one powder, amongst powders used to prepare a solid-state battery electrolyte. According to an embodiment, the powder to be sprayed is a single powder, or a mixed powder of more than one powder, amongst powders used to prepare a sodium ion battery positive/negative electrode material.

According to an embodiment, the powders that may be used to prepare a solid-state battery electrolyte include lithium phosphate, lithium silicate, silicon nitride, lithium iron phosphate, Li(NiCoSi)O2, Li(Mn2O4), silicon, graphite, LiTiO3, LLTO, LLZO, lithium cobaltate, and such equivalents. According to an embodiment, the powders that may be used to prepare a sodium ion battery positive/negative electrode material include sodium-transition metal oxides, sodium-transition metal phosphates and variants, sodium-transition metal sulfates, sodium-transition metal Prussian blue compounds, hard carbon, soft carbon, alloys, transition metal oxides, and such equivalents.

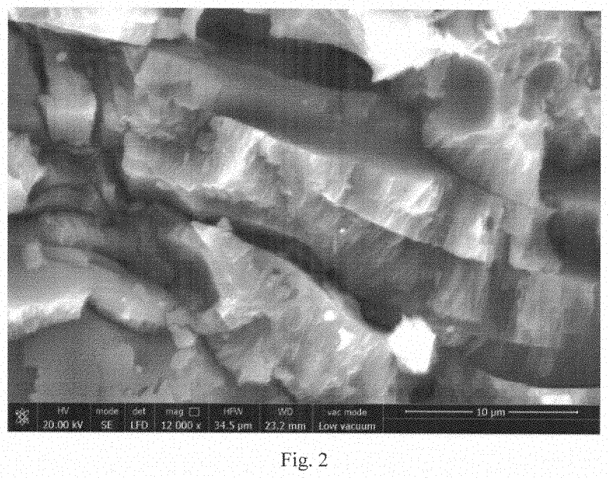

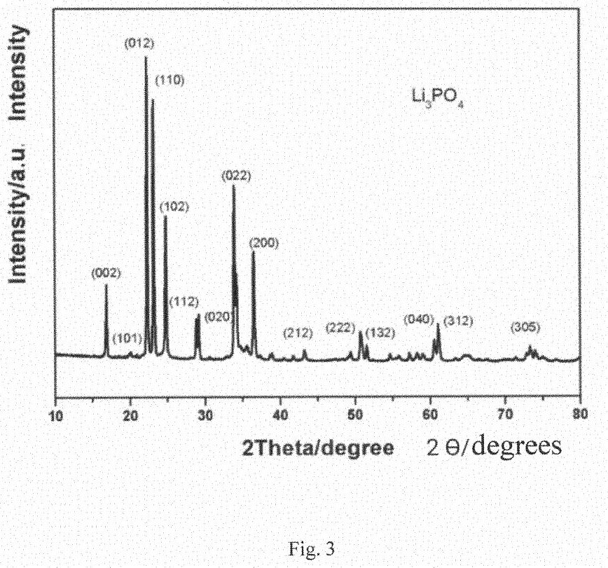

As shown in FIGS. 2 and 3, taking Li₃PO₄ powder as an example, an Li₃PO₄ target prepared using the plasma spray method disclosed in the present invention shows a nearly pure Li₃PO₄ phase under SEM and XRD analysis, consistent with an initial Li₃PO₄ powder composition. The preparation process disclosed in the present invention is not only suitable for electrolyte material selection, Li₃PO₄ and ceramic materials similar thereto, but is also suitable for electrodes, such as LiCoO₂, etc. Plasma spray is suitable for mass production and low-cost production.

Compared with an existing process method: (1) There is no need for welding, and the target material is sprayed directly onto the substrate; (2) adjustment can be carried out according to different sizes, and there are no fundamental size restrictions; (3) there are no fundamental restrictions on the target thickness, in particular in the case of thin targets, which are very difficult to prepare by other methods, especially thin targets with large surface areas; (4) there are no restrictions on target shape, e.g. planar and rotary are both possible; (5) a used target can be re-sprayed for re-use, with no need to remove all of the residual material; (6) the spray process can be integrated into a physical vapor deposition (PVD) process flow line, to maintain the same thickness in each PVD treatment; (7) adhesion to various substrate materials is strong; (8) it can be used to form a thin film directly, not only to manufacture a target; (9) it can be used for non-reactive, and even reactive deposition of pure powders or mixed powders; (10) it has cyclic deposition/plasma surface treatment process capability; and (11) different materials can be deposited in layers or in a pattern using the same target.

Various modifications to these embodiments are apparent to those skilled in the art from the description and the accompanying drawings. The principles associated with the various embodiments described herein may be applied to other embodiments. Therefore, the description is not intended to be limited to the embodiments shown along with the accompanying drawings but is to be providing broadest scope of consistent with the principles and the novel and inventive features disclosed or suggested herein. Accordingly, the disclosure is anticipated to hold on to all other such alternatives, modifications, and variations that fall within the scope of the present disclosure and appended claim.

1. A method for preparing a sputtering target that utilizes plasma spray technology, the method comprising:
preparing a powder to be sprayed to a particle size range that is usable for a plasma spray;
subjecting a surface of a substrate to surface treatment;
spraying the powder onto the treated surface of the substrate using a plasma sprayer to form the sputtering target;
cleaning the sputtering target.

2. The method of claim 1, wherein spraying the powder onto the treated surface of the substrate comprises:
blowing a working gas into a plasma generation region, under atmospheric-pressure or reduced-pressure conditions;
setting an arc direct-current power of the plasma sprayer, and once an arc has stabilized, using a carrier gas to feed the powder to be sprayed into a plasma stream; and
adjusting a spray distance between a spray gun of the plasma sprayer and the treated surface of the substrate, and moving the spray gun of the plasma sprayer to uniformly spray the powder to be sprayed onto a designated region of the substrate.

3. The method of claim 2, the working gas comprises one or mixture of Ar, N₂, O₂, NH₃, air, and another inert gas, and wherein the working gas is blown into the plasma generation region at a flow speed of 1-100 L/min.

4. The method of claim 2, further comprising while the working gas is blown into the plasma generation region, adding H₂ as a secondary working gas.

5. The method of claim 2, wherein the powder to be sprayed is fed into the plasma stream by the carrier gas at a rate of 1-100 g/min.

6. The method of claim 2, wherein the arc direct-current power of the plasma sprayer is 1-400 kW.

7. The method of claim 2, wherein the spray distance is 20-200 mm, and the spray gun of the plasma sprayer moves at a speed of 2-500 cm/s.

8. The method of claim 2, further comprising when the powder to be sprayed is sprayed uniformly onto the designated region of the substrate by the spray gun, a cooling gas stream is blown around a spray flame to control the temperature of the substrate.

9. The method of claim 2, further comprising when the powder to be sprayed is sprayed uniformly onto the designated region of the substrate by the spray gun, cooling water is passed at opposite surface of the substrate to control the temperature of the substrate.

10. The method of claim 8, wherein the temperature of the substrate is controlled so as to be less than or equal to 90% of the melting point of the powder to be sprayed.

11. The method of claim 1, wherein the particle size range of the powder to be sprayed after processing is 5-500 um.

12. The method of claim 1, wherein the surface treatment comprises at least one of a treatment to enhance adhesion, a treatment to adjust a thermal expansion coefficient mismatch, a contaminant reduction treatment, a surface roughness treatment, and a treatment to add a surface transition layer.

13. The method of claim 1, wherein the substrate is one of a floating ground, connected to ground, and has a direct-current voltage bias.

14. The method of claim 1, wherein the substrate is one of a pure metal, an alloy and an electrically conductive non-metal material.

15. The method of claim 1, wherein the powder to be sprayed comprises at least one type of powder amongst a plurality of types of powders used to prepare electrolyte film for one of a lithium ion and sodium ion solid-state thin film batteries.

16. The method of claim 1, wherein the powder to be sprayed comprises at least one kind of powder amongst a plurality of types of powders used to prepare a thin film battery positive/negative electrode material.

17. The method of claim 15, wherein the powders used to prepare a solid-state battery electrolyte include lithium phosphate, lithium silicate, silicon nitride, lithium iron phosphate, Li(NiCoSi)O2, Li(Mn2O4), silicon, graphite, LiTiO3, LLTO, LLZO and lithium cobaltate, the powders used to prepare a sodium ion battery positive/negative electrode material include sodium-transition metal oxides, sodium-transition metal phosphates and variants, sodium-transition metal sulfates, sodium-transition metal Prussian blue compounds, hard carbon, soft carbon, alloys and transition metal oxides.
